(19) United States
(12) Patent Application Publication
(10) Pub. No.: US 2024/0005128 A1
(43) Pub. Date: Jan. 4, 2024

(54) PREDICTION METHOD, INFORMATION PROCESSING APPARATUS, FILM FORMING APPARATUS, ARTICLE MANUFACTURING METHOD AND NON-TRANSITORY STORAGE MEDIUM

(71) Applicant: CANON KABUSHIKI KAISHA, Tokyo (JP)

(72) Inventors: NAOKI KIYOHARA, Tokyo (JP); SENTARO AIHARA, Tochigi (JP); YUICHIRO OGUCHI, Tokyo (JP)

(21) Appl. No.: 18/336,149

(22) Filed: Jun. 16, 2023

(30) Foreign Application Priority Data
Jul. 1, 2022 (JP) 2022-107359

(51) Int. Cl. G06N 3/04; G06N 3/08

(52) U.S. Cl. CPC G06N 3/04; G06N 3/08

(57) ABSTRACT

A prediction method of predicting a behavior of droplets of a curable composition in a process of forming a film of the curable composition from a plurality of droplets of the curable composition arranged on a first member, the method including predicting the behavior of the droplets using a learning model, wherein an input of the learning model includes first information indicating positions on the first member to which the droplets of the curable composition are to be arranged.

### BACKGROUND OF THE INVENTION

### Field of the Invention

The present invention relates to a prediction method, an information processing apparatus, a film forming apparatus, an article manufacturing method and a non-transitory storage medium.

### Description of the Related Art

There is provided a film forming technique of forming a film made of a curable composition on a substrate by arranging the curable composition on the substrate, bringing the curable composition into contact with a mold, and curing the curable composition. Such a film forming technique is applied to an imprint technique and a planarization technique. In the imprint technique, by using a mold having a pattern, the pattern of the mold is transferred to a curable composition on a substrate by bringing the curable composition on the substrate into contact with the pattern of the mold and curing the curable composition. In the planarization technique, by using a mold having a flat surface, a film having a flat upper surface is formed by bringing a curable composition on a substrate into contact with the flat surface and curing the curable composition.

The curable composition is arranged in the form of droplets on the substrate, and the mold is then pressed against the droplets of the curable composition. This spreads the droplets of the curable composition on the substrate, thereby forming a film of the curable composition. At this time, it is important to form a film of the curable composition with a uniform thickness and not to leave bubbles in the film. To achieve this, the arrangement pattern of the droplets of the curable composition, a method and a condition for pressing the mold against the curable composition, and the like are adjusted. To implement this adjustment operation by trial and error using an apparatus, enormous time and cost are required. To cope with this, development of a simulator that supports such adjustment operation is desired.

Japanese Patent No. 5599356 discloses a simulation method for predicting wet spreading and gathering of a plurality of droplets arranged on a pattern forming surface, and a method of generating a droplet arrangement pattern utilizing the prediction. Japanese Patent No. 5599356 discloses a simulator that predicts the behavior of the droplets of a curable composition by physical calculation.

In the conventional technique, physical calculation is used to predict the behavior of the droplets of a curable composition. However, when adjusting the arrangement pattern of the droplets of the curable composition, the method and the condition for pressing the mold against the curable composition, and the like, repetitive simulation is required. Particularly, when adjusting the arrangement pattern of the droplets of the curable composition, since the number of combinations of the arrangement patterns of the droplets of the curable composition is enormous, enormous calculation time is required for the simulation including physical calculation.

### SUMMARY OF THE INVENTION

The present invention provides a technique advantageous in predicting the behavior of the droplets of a curable composition in a process of forming a film of the curable composition.

According to one aspect of the present invention, there is provided a prediction method of predicting a behavior of droplets of a curable composition in a process of forming a film of the curable composition from a plurality of droplets of the curable composition arranged on a first member, the method including predicting the behavior of the droplets using a learning model, wherein an input of the learning model includes first information indicating positions on the first member to which the droplets of the curable composition are to be arranged.

Further aspects of the present invention will become apparent from the following description of exemplary embodiments with reference to the attached drawings.

### BRIEF DESCRIPTION OF THE DRAWINGS

FIGS. 1A and 1B are views explaining a film forming apparatus according to an embodiment of the present invention.

FIGS. 2A to 2F are views showing spreading of droplets of a curable composition on a substrate.

FIG. 3 is a view showing the configuration of a prediction system according to the embodiment of the present invention.

FIG. 4 is a block diagram showing the hardware arrangement of a prediction server.

FIG. 5 is a view explaining a graph convolutional network.

FIG. 6 is a view explaining weights between layers in a graph neural network in detail.

FIG. 7 is a flowchart for explaining a process of generating a learning model using the graph neural network.

FIG. 8 shows views explaining a process of generating graphs.

FIG. 9 shows views explaining a process of assigning feature amounts to graphs.

FIGS. 10A and 10B are views explaining a process of generating learning data from measurement data.

FIG. 11 is a view showing an example of the graph neural network set as the learning model.

FIG. 12 is a flowchart for explaining a process of predicting the behavior of the droplets of the curable composition.

FIGS. 13A and 13B are views explaining an example of the result predicted from an input parameter.

FIG. 14 is a view showing an example of a neural network.

FIGS. 15A and 15B are views explaining input data used for prediction using the neural network.

FIGS. 16A and 16B are views explaining learning data used for learning using the neural network.

FIGS. 17A to 17F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

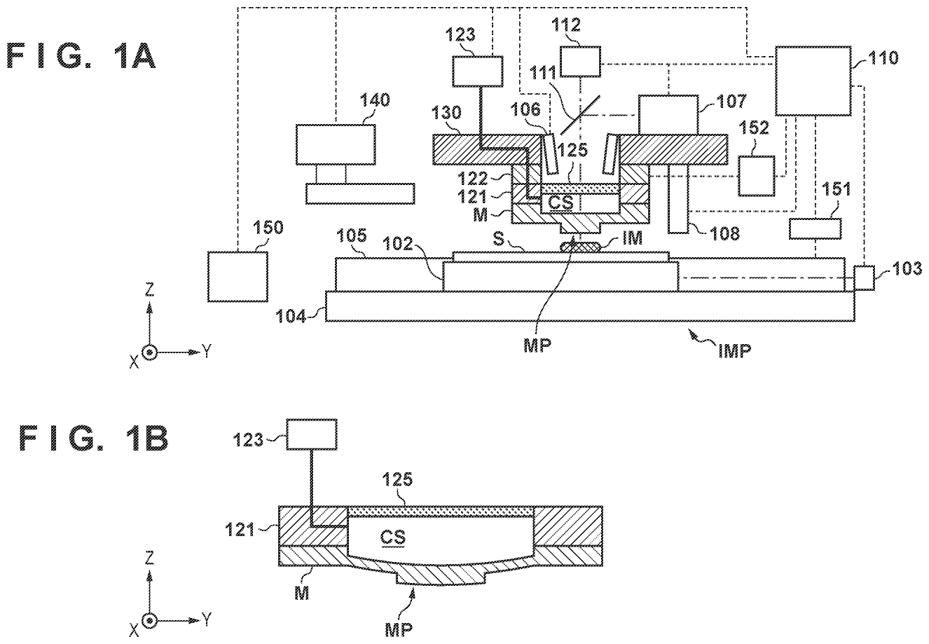

FIGS. 1A and 1B are views explaining a film forming apparatus IMP according to an embodiment of the present invention. The film forming apparatus IMP executes a process of forming a film of a curable composition IM from a plurality of droplets of the curable composition IM arranged on a substrate S, for example, a process of forming a film of the curable composition IM in a space between the substrate S and a mold M by bringing the plurality of droplets of the curable composition IM and the mold M into contact with each other. The film forming apparatus IMP may be formed as, for example, an imprint apparatus or a planarization apparatus.

Here, the substrate S and the mold M are interchangeable, and a film of the curable composition IM may be formed in the space between the mold M and the substrate S by bringing the plurality of droplets of the curable composition IM arranged on the mold M into contact with the substrate S. Accordingly, the film forming apparatus IMP is comprehensively an apparatus that executes a process of bringing a plurality of droplets of the curable composition IM arranged on a first member into contact with a second member, thereby forming a film of the curable composition IM in a space between the first member and the second member. This embodiment provides a description assuming the first member as the substrate S and the second member as the mold M. However, the first member may be assumed as the mold M and the second member may be assumed as the substrate S. In this case, the substrate S and the mold M in the following description are interchanged.

The imprint apparatus uses the mold M having a pattern to transfer the pattern of the mold M to the curable composition IM on the substrate S. The imprint apparatus uses the mold M having a pattern region MP provided with a pattern. As an imprint process, the imprint apparatus brings the curable composition IM on the substrate S into contact with the pattern region MP of the mold M, fills, with the curable composition IM, the space between the mold M and a region of the substrate S where the pattern is to be formed, and then cures the curable composition IM. This transfers the pattern in the pattern region IM of the mold M to the curable composition IM on the substrate S. For example, the imprint apparatus forms a pattern made of a cured product of the curable composition IM in each of a plurality of shot regions of the substrate S.

As a planarization process, the planarization apparatus uses the mold M having a flat surface, brings the curable composition IM on the substrate S into contact with the flat surface of the mold M, and cures the curable composition IM, thereby forming a film having a flat upper surface. If the mold M having dimensions (size) that cover the entire region of the substrate S is used, the planarization apparatus forms a film made of a cured product of the curable composition IM in the entire region of the substrate S. Note that the planarization apparatus may execute a process of forming a film of the curable composition IM on the substrate S from a plurality of droplets of the curable composition IM arranged on the substrate S without bringing the mold M into contact with the plurality of droplets.

As the curable composition, a material to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used. Thus, the curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like. The viscosity (the viscosity at 25° C.) of the curable composition is, for example, 1 mPa·s (inclusive) to 100 mPa·s (inclusive).

As a material of the substrate, glass, ceramic, a metal, a semiconductor, a resin, or the like is used. A member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to the surface of the substrate S are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that is specified based on coordinates on the X-, Y-, and Z-axes, and an orientation is information that is specified by values on the θX-, θY-, and θZ-axes. Positioning means controlling the position and/or orientation. Alignment includes a control of the position and/or orientation of at least one of substrate S and mold M.

The film forming apparatus IMP includes a substrate holding unit 102 that holds the substrate S, a substrate driving mechanism 105 that drives the substrate S by driving the substrate holding unit 102, a base 104 that supports the substrate driving mechanism 105, and a position measurement unit 103 that measures the position of the substrate holding unit 102. The substrate driving mechanism 105 includes, for example, a motor such as a linear motor.

The film forming apparatus IMP includes a sensor 151 that measures the substrate driving force (alignment load) required for the substrate driving mechanism 105 to drive the substrate S (substrate holding unit 102) during alignment. The substrate driving force in an alignment operation, which is performed in a state in which the curable composition IM on the substrate S and the pattern region MP of the mold M are in contact with each other, corresponds to, for example, a shear force that acts between the substrate S and the mold M. The shear force is mainly a force that acts in the plane direction of the substrate S and the mold M. The substrate driving force during alignment is, for example, correlated to the magnitude of a current supplied to the substrate driving mechanism 105 (motor thereof) during alignment. Accordingly, the sensor 151 can obtain the substrate driving force by detecting the current (magnitude thereof) supplied to the substrate driving mechanism 105. In this manner, the sensor 151 functions as a sensor for measuring the influence (shear force) received by the mold M during pattern formation. Note that a driving request (command value) output from a control unit 110 (to be described later) to the substrate driving mechanism 105 is referred to as a stage control value.

The film forming apparatus IMP includes a mold holding unit 121 that holds the mold M, a mold driving mechanism 122 that drives the mold M by driving the mold holding unit 121, and a support structure 130 that supports the mold driving mechanism 122. The mold driving mechanism 122 includes, for example, a motor such as a voice coil motor.

The film forming apparatus IMP includes a sensor 152 that measures a mold releasing force (separation load) and/or a pressing force (imprint force). The mold releasing force is a force required to release (separate) the cured product of the imprint material IM on the substrate S and the mold M from each other. The pressing force is a force of pressing the mold M to bring the mold M into contact with the curable composition IM on the substrate S. The mold releasing force and the pressing force are forces that act in a direction perpendicular to the plane direction of the substrate S and the mold M. Each of the mold releasing force and the pressing force is, for example, correlated to the magnitude of the current supplied to the mold driving mechanism 122 (motor thereof). Accordingly, the sensor 152 can obtain the mold releasing force and/or the pressing force by detecting the current (magnitude thereof) supplied to the mold driving mechanism 122. In this manner, the sensor 152 functions as a sensor for measuring the influence (the mold releasing force and/or the pressing force) received by the mold M during the pattern formation. Note that a driving request (command value) output from the control unit 110 (to be described later) to the mold driving mechanism 122 is referred to as a stage control value.

The substrate driving mechanism 105 and the mold driving mechanism 122 form a relative driving mechanism that drives at least one of the substrate S and the mold M so as to adjust the relative position between the substrate S and the mold M. Adjustment of the relative position between the substrate S and the mold M by the relative driving mechanism includes driving for bringing the curable composition IM on the substrate S into contact with the mold M and driving for separating the mold M from the cured curable composition IM (the pattern of a cured product) on the substrate S. In addition, adjustment of the relative position between the substrate S and the mold M by the relative driving mechanism includes alignment between the substrate S and the mold M. The substrate driving mechanism 105 is configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The mold driving mechanism 122 is configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis).

The film forming apparatus IMP includes a mold conveyance mechanism 140 that conveys the mold M, and a mold cleaner 150. The mold conveyance mechanism 140 is configured to, for example, convey the mold M to the mold holding unit 121, and convey the mold M from the mold holding unit 121 to a stocker (not shown) or the mold cleaner 150. The mold cleaner 150 cleans the mold M using ultraviolet rays, a chemical solution, or the like.

The film forming apparatus IMP includes a window member 125 for forming a pressure control space CS on the side of the back surface (the surface on the opposite side of the pattern region MP of the mold M) of the mold M. The window member 125 is formed of a material that transmits curing energy from a curing unit 107, and allows application of the curing energy to the curable composition IM on the substrate S. The film forming apparatus IMP includes a deformation mechanism 123 that deforms the pattern region MP of the mold M into a convex shape toward the substrate S as schematically shown in FIG. 1B by controlling the pressure (to be referred to as the “cavity pressure” hereinafter) in the pressure control space CS.

The film forming apparatus IMP includes an alignment measurement system 106 that illuminates alignment marks respectively provided in the substrate S (shot region thereof) and the mold M and captures images of the alignment marks, thereby measuring the relative position between the marks. The film forming apparatus IMP may include a plurality of the alignment measurement systems 106 to simultaneously observe a plurality of alignment marks respectively provided in the substrate S and the mold M. For example, the film forming apparatus IMP includes four alignment measurement systems 106 that observe alignment marks provided in four corners of the shot region of the substrate S and alignment marks provided in four corners of the mold M. The alignment measurement system 106 may be positioned by a driving mechanism (not shown) in accordance with the positions of the alignment marks. Note that an image captured by the alignment measurement system 106 is also referred to as an alignment image. The alignment image includes, for example, an image obtained by capturing reflected light from the alignment marks of the substrate S and the mold M, an image obtained by capturing the image formed by moire of the alignment marks of the substrate S and the mold M, and the like

The film forming apparatus IMP includes the curing unit 107 for curing the curable composition IM on the substrate S. The curing unit 107 curing the curable composition IM by irradiating the curable composition IM with energy for curing the curable composition IM, for example, light such as ultraviolet rays via an optical member 111.

The film forming apparatus IMP includes an image capturing unit 112 that captures images of the mold M, the substrate S, and the curable composition IM on the substrate S via the optical member 111 and the window member 125. Note that the image captured by the image capturing unit 112 may also be referred to as a spread image.

The film forming apparatus IMP includes a dispenser 108 used to arrange, supply, or distribute the curable composition IM on the substrate S. The dispenser 108 discharges the curable composition IM so as to arrange the droplets of the curable composition IM on the substrate S in accordance with, for example, the arrangement pattern indicating positions on the substrate S to which the droplets of the curable composition IM are to be arranged.

The film forming apparatus IMP includes the control unit 110 that operates the film forming apparatus IMP by comprehensively controlling the respective units of the film forming apparatus IMP. The control unit 110 is formed by, for example, a PLD (the abbreviation of a Programmable Logic Device) such as an FPGA (the abbreviation of a Field Programmable Gate Array), an ASIC (the abbreviation of an Application Specific Integrated Circuit), a general-purpose computer installed with a program, or a combination of all or some of these components.

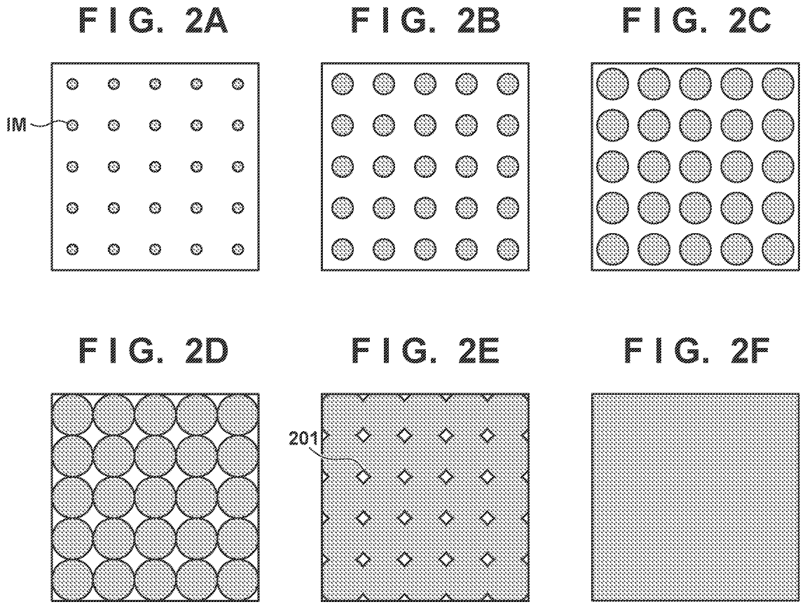

FIGS. 2A to 2F are views showing spreading of the droplets of the curable composition IM in a process of pressing the mold M against the curable composition IM on the substrate S. FIG. 2A shows a state immediately after the droplets of the curable composition IM are arranged on the substrate S from the dispenser 108. Referring to FIG. 2A, in the state immediately after the droplets of the curable composition IM are arranged, respective droplets are small and separated from each other. By pressing the mold M, the droplets of the curable composition IM arranged on the substrate S gradually spread from the state shown in FIG. 2A to the states shown in FIGS. 2B to 2E, and adjacent droplets come into contact with each other. Finally, the droplets of the curable composition IM arranged on the substrate S spread over the entire region of the mold M (pattern region MP).

In the process in which the curable composition IM on the substrate S spreads, bubbles 201 are formed (trapped) among the adjacent droplets of the curable composition IM as shown in FIG. 2E. If the curable composition IM is cured in the state in which the bubble 201 exists, the portion where the bubble 201 exists becomes a defect. Accordingly, in order to improve the production performance of the film forming apparatus IMP, it is important to decrease the size of the bubble 201 formed among the adjacent droplets of the curable composition IM and make the bubble 201 disappear in a short time.

Therefore, in this embodiment, a prediction system (simulation system) that predicts the behavior of the droplets of the curable composition IM in a process executed in the film forming apparatus IMP is provided. The prediction system predicts, using machine learning in place of physical calculation, the complex behavior involving the occurrence situation of the bubbles 201 and the interaction between the droplets in a process of forming a film of the curable composition IM in a space between the substrate S and the mold M, for example, in an imprint process.

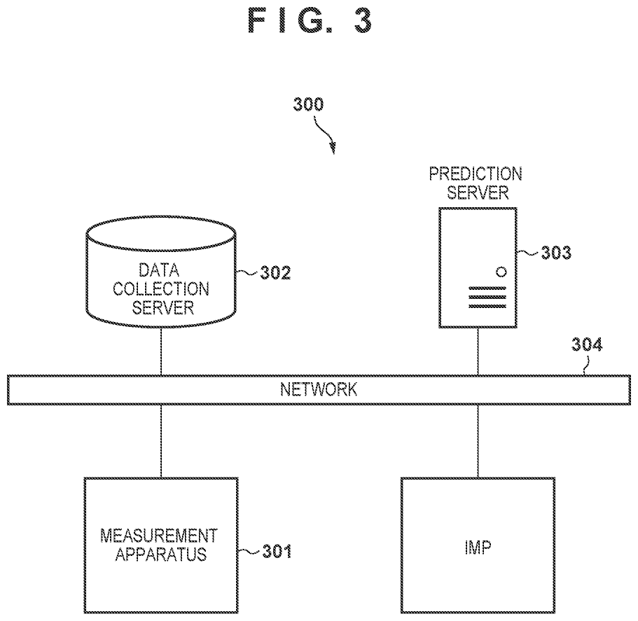

FIG. 3 is a view showing the configuration of a prediction system 300 that predicts the behavior of the droplets of the curable composition 1M arranged on the substrate S. The prediction system 300 includes a measurement apparatus 301, a data collection server 302, and a prediction server 303 (simulation server).

The prediction server 303 is an information processing apparatus (simulation apparatus) that predicts, using machine learning, the behavior of the droplets of the curable composition IM arranged on the substrate S. Data required for machine learning performed by the prediction server 303 is collected from the data collection server 302 via a network 304.

The measurement apparatus 301 is an apparatus that measures (inspects) the state of the substrate S processed by the film forming apparatus IMP, that is, the state (defect and the like) of the film of the curable composition IM formed on the substrate. The measurement result measured by the measurement apparatus 301 is accumulated in the data collection server 302 via the network 304.

The data collection server 302 receives the measurement result from the measurement apparatus 301 via the network 304, and accumulates the measurement result as measurement data. Further, the data collection server 302 transmits the measurement data to the prediction server 303 via the network 304.

The film forming apparatus IMP adjusts, based on the behavior of the droplets of the curable composition IM predicted by the prediction server 303, the arrangement pattern of the droplets of the curable composition IM, the method and condition for pressing the mold M against the curable composition IM, and the like.

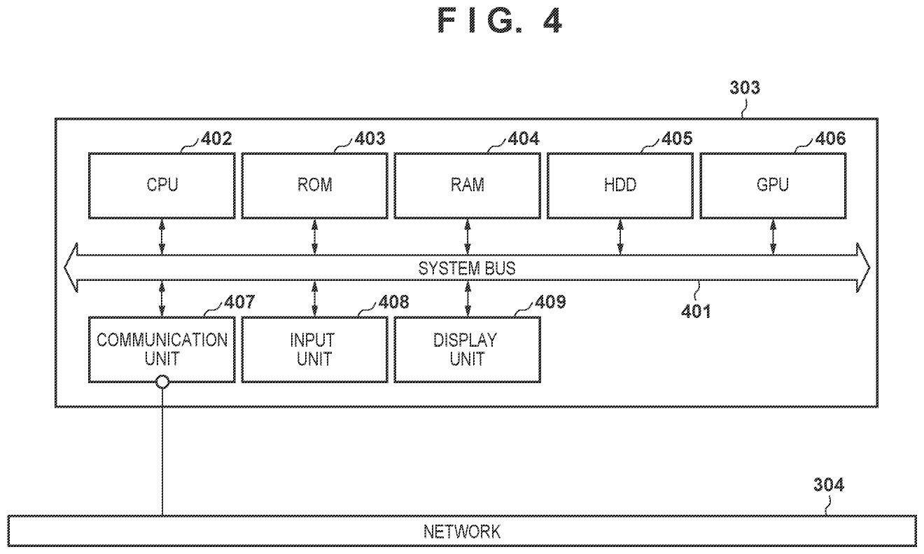

FIG. 4 is a block diagram showing the hardware arrangement of the prediction server 303. The prediction server 303 includes a system bus 401, a CPU 402, a ROM 403, a RAM 404, an HDD 405, a GPU 406, a communication unit 407, an input unit 408, and a display unit 409. Each unit of the prediction server 303 operates (functions) in accordance with a program.

The CPU 402 performs calculations for controlling the respective units of the prediction server 303 connected to the system bus 401 in accordance with the program. The ROM 403 is a data read-only memory. The ROM 403 stores programs and data. The RAM 404 is a data read/write memory, and used to save programs and data. The RAM 404 is also used to temporarily save data such as a result of calculation performed by the CPU 402.

The HDD 405 is used as the save area for the program of the Operating System (OS) of the prediction server 303 and the temporary save area for programs and data. The HDD 405 is slower to input and output data than the RAM 404, but can save a large amount of data. The HDD 405 is preferably a non-volatile storage apparatus that can permanently save data so that data can be referred to over a long period of time. In this embodiment, the HDD 405 is provided as the storage apparatus, but the present invention is not limited to this, and an apparatus may be provided that reads and writes data from/in an external medium such as a CD, a DVD, or a memory card loaded to the apparatus.

The GPU 406 is an arithmetic processing apparatus that can perform more parallel calculation processing operations than the CPU 402. In this embodiment, some of inference processing and learning processing in machine learning are performed by the GPU 406 in accordance with the contents of the program.

The communication unit 407 performs data communication by a communication protocol such as TCP/IP via the network 304. The communication unit 407 is used when performing mutual communication with another apparatus. The input unit 408 is an apparatus that includes various kinds of keyboards, a mouse, and the like, and used to input information (for example, characters, data, and the like) required for the prediction server 303. The display unit 409 is an apparatus that includes a CRT, a liquid crystal monitor, or the like, and used to display information required for the operation of the prediction server 303, a processing result (prediction result), and the like.

As has been described above, the prediction server 303 predicts, using machine learning, the behavior of the droplets of the curable composition IM arranged on the substrate S. At this time, in order to predict the mutual relationship among the adjacent droplets of the curable composition IM, it is effective to use a graph neural network as the learning model.

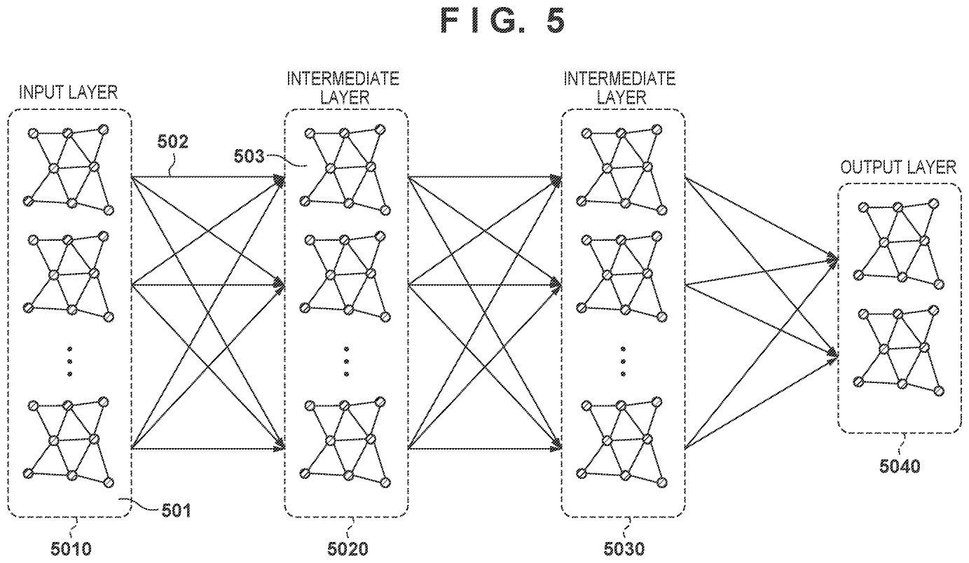

FIG. 5 is a view explaining a graph convolutional network as an example of the graph neural network. The graph neural network is formed from layers including an input layer 5010, one or a plurality of intermediate layers (hidden layers) 5020 and 5030, and an output layer 5040. Each layer includes a plurality of graphs as elements, and the node of each graph has a feature amount.

Learning in the graph neural network is performed by updating the weight associated between the front layer and the rear layer. Such the weight between the layers is expressed by a matrix. For example, a weight 502 expresses the weight between a graph 501 included in the input layer 5010 and a graph 503 included in the intermediate layer 5020. When learning the graph neural network, the weight is updated in accordance with the error between the learning data and the result (prediction result) predicted from the learning data.

In this manner, in the graph neural network, each layer includes graphs as elements. In the learning process, the weight between the layers is updated so as to decrease the error between the learning data and the prediction result of the graph neural network.

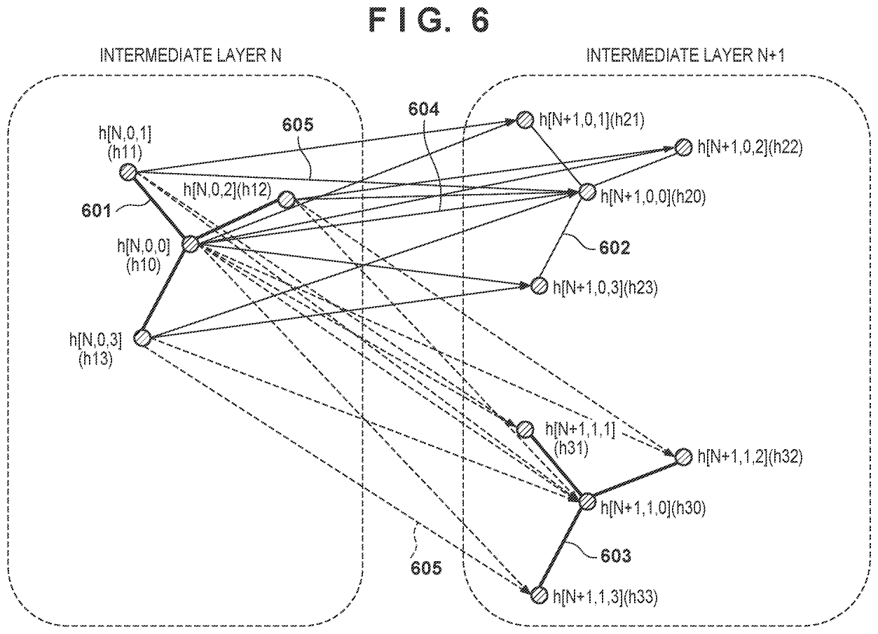

FIG. 6 is a view explaining weights between layers in the graph neural network in detail. An intermediate layer N as the front layer includes a graph 601, and an intermediate layer N+1 as the rear layer includes a graph 602 and a graph 603. In FIG. 6, the weight between the graph 601 and the graph 602 is indicated by a solid arrow, and the weight between the graph 601 and the graph 603 is indicated by a dashed arrow.

The graph 601 is formed from four nodes h[N, 0, 0], h[N, 0, 1], h[N, 0, 2], and h[N, 0, 3], and each node holds a feature amount. The graph 602 is formed from four nodes h[N+1, 0, 0], h[N+1, 0, 1], h[N+1, 0, 2], and h[N+1, 0, 3], and each node holds a feature amount. Similarly, the graph 603 is formed from four nodes h[N+1, 1, 0], h[N+1, 1, 1], h[N+1, 1, 2], and h[N+1, 1, 3], and each node holds a feature amount.

Note that the four nodes h[N, 0, 0], h[N, 0, 1], h[N, 0, 2], and h[N, 0, 3] forming the graph 601 are referred to as nodes h10, h11, h12, and 13, respectively, hereinafter. In addition, the four nodes h[N+1, 0, 0], h[N+1, 0, 1], h[N+1, 0, 2], and h[N+1, 0, 3] forming the graph 602 are referred to as nodes h20, h21, h22, and h23, respectively, hereinafter. Similarly, the four nodes h[N+1, 1, 0], h[N+1, 1, 1], h[N+1, 1, 2], and h[N+1, 1, 3] forming the graph 603 are referred to as nodes h30, h31, h32, and h33, respectively, hereinafter.

A specific example of the weight between the graphs is a weight 604 between the node h10 of the intermediate layer N and the corresponding node h20 of the intermediate layer N+1. In addition to this, the node of the intermediate layer N+1 is also applied with the weight from the node adjacent to its corresponding node in the intermediate layer N. For example, the node h20 of the intermediate layer N+1 may hold a value expressed by the total sum of the value of its corresponding node h10 of the intermediate layer N multiplied by the weight 604 and the values of the nodes h11, h12, and h13 adjacent to the node h10 multiplied by a weight 605. Alternatively, the node h20 of the intermediate layer N+1 may hold a value obtained by applying some aggregation operation to this total sum and applying a non-linear function as an activation function. With this, the feature amount of each node of the intermediate layer N+1 includes the information concerning the feature amount of the adjacent node in the intermediate node N. More specifically, the node h20 of the intermediate layer N+1 receives the influence of the feature amounts of the nodes h11, h12, and h13 in addition to the feature amount of its corresponding node h10 in the intermediate layer N.

In this manner, in the graph convolutional network, the corresponding node and the nodes adjacent thereto in the front layer are input to the node in the rear layer. This enables machine learning considering the influences of the adjacent nodes and, further, the nodes in a wider region.

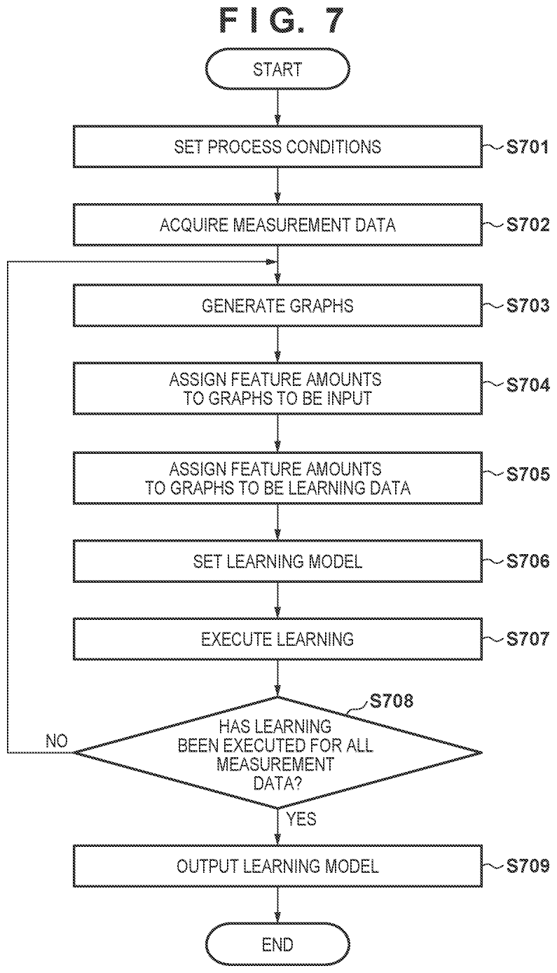

FIG. 7 is a flowchart for explaining a process of generating a learning model using the graph neural network. The process of generating the learning model is executed by the prediction server 303.

In step S701, conditions (process conditions) required for a process (for example, imprint process) of forming a film of the curable composition IM in a space between the substrate S and the mold M are set. The process conditions include, for example, the arrangement pattern indicating positions on the substrate S to which the droplets of the curable composition IM are to be arranged, the shape of the pattern of the mold M, the target value of the thickness of the film of the curable composition IM to be formed on the substrate S, the depth of the pattern (groove) in the pattern region MP of the mold M, and the like.

In step S702, measurement data corresponding to the process conditions set in step S701, that is, measurement data of the state of the substrate S (the state of the film of the curable composition IM formed on the substrate) processed using these process conditions is acquired from the data collection server 302. More specifically, the prediction server 303 requests, via the network 304, the data collection server 302 for measurement data corresponding to the process conditions set in step S701. In response to the request from the prediction server 303, the data collection server 302 extracts measurement data (data group) corresponding to the process conditions set in step S701 from measurement data accumulated as a database. Then, the data collection server 302 makes a list of the measurement data extracted from the database, and transmits the list to the prediction server 303 via the network 304.

In step S703, graphs included in each layer in the graph neural network are generated.

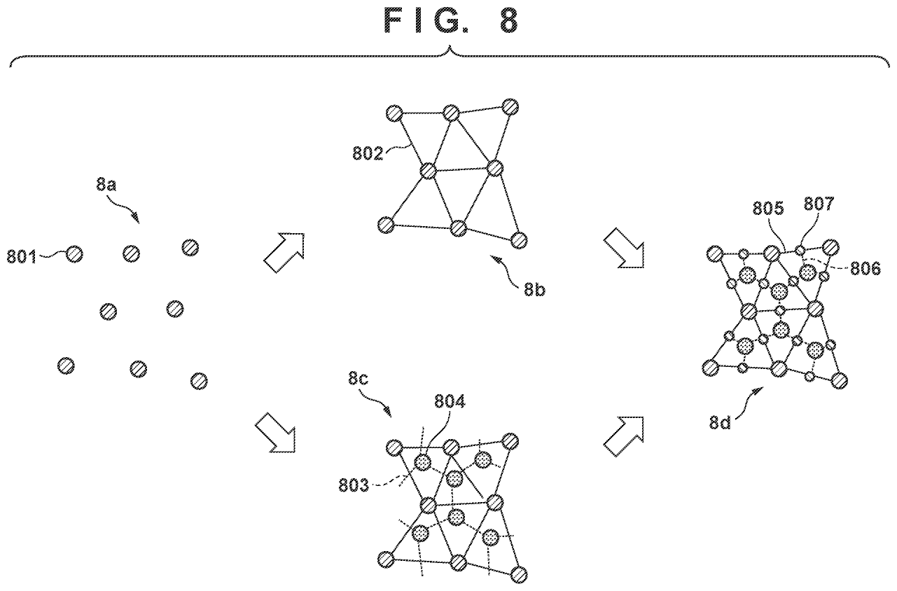

Here, with reference to FIG. 8, a process of generating a graph will be described. 8a shows an arrangement pattern 801 of the droplets of the curable composition IM set as the process condition in step S701. As shown in 8a, the arrangement pattern 801 is information (first information) including the coordinates (position) of each droplet of the curable composition IM.

In this embodiment, a graph shown in 8b is generated based on the arrangement pattern 801 of the droplets of the curable composition IM. In the graph shown in 8b, each line connecting the positions corresponding to the respective droplets of the curable composition IM included in the arrangement pattern 801, that is, each line connecting adjacent droplets (nodes) with the center position of the droplet as the node is set as a link 802. An example of the method of generating such the graph is a method using a Delaunay diagram while setting each droplet of the curable composition IM as the node.

Further, in this embodiment, a graph shown in 8c is generated based on the arrangement pattern 801 of the droplets of the curable composition IM. In the graph shown in 8c, a node 804 is arranged in a region surrounded by the droplets of the curable composition IM. In other words, the node 804 is set at the position in the region defined by the adjacent droplets of the plurality of droplets of the curable composition IM. Note that the node 804 is preferably arranged at the midpoint among the adjacent droplets of the curable composition IM (the centroid position of the region defined by the adjacent droplets). An example of the method of generating such the graph is a method using a Voronoi diagram while setting each droplet of the curable composition IM as the node. The Voronoi diagram is a diagram dividing a plane based on the closest point. 8c shows boundary lines 803 (Voronoi boundaries) of the regions (divided regions) obtained by division. In this manner, the region defined by the adjacent droplets of the plurality of droplets of the curable composition IM is a region divided by Voronoi boundaries of a Voronoi diagram in which each of the plurality of droplets is set as a generating point. A bubble (defect), which is generated in the film of the curable composition IM, tends to be generated on the boundary line 803 far from the respective droplets of the curable composition IM. Therefore, in the Voronoi diagram, the intersection point where the boundary lines 803 intersect is set as the node 804, and a line connecting the nodes 804 (nodes) is set as a link (boundary line 803), thereby generating the graph shown in 8c. Note that the node 804 is not limited to the intersection point where the boundary liens 803 intersect, but may be set so as to include the boundary line 803. That is, the node 804 may be set on the boundary line 803.

8d shows a graph generated by combining the graph shown in 8b and the graph shown in 8c. The graph shown in 8d takes over the nodes and links of the graphs shown in 8b and 8c. Further, in the graph shown in 8d, new nodes 807 are added at intersection points (portions) at each of which a link 805 taking over the link 802 of the graph shown in 8b and a link 806 taking over the link (boundary line 803) of the graph shown in 8c intersect.

In this manner, in step S703, the graph shown in 8b, the graph shown in 8c, and the graph shown in 8d are generated based on the arrangement pattern 801 of the droplets of the curable composition IM shown in 8a. These graphs are information (second information) indicating the relative positional information of the adjacent droplets in the plurality of droplets of the curable composition IM. In this embodiment, the graph shown in 8b, the graph shown in 8c, and the graph shown in 8d, which are generated from the arrangement pattern 801 shown in 8a, are used as inputs of the graph neural network.

Referring back to FIG. 7, in step S704, feature amounts are assigned to graphs which will be used as inputs of the graph neural network, that is, the graphs generated in step S703.

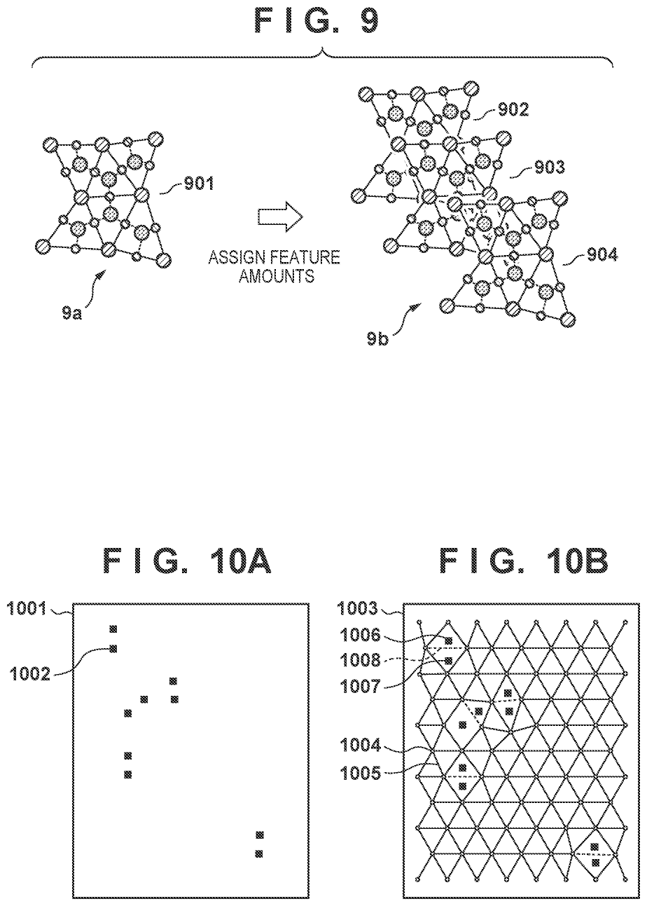

Here, with reference to FIG. 9, a process of assigning feature amounts to graphs, which will be used as inputs of the graph neural network, will be described. 9a shows a graph 901 generated in step S703. As the feature amounts assigned to the graph 901, for example, information concerning the position and volume of the droplet of the curable composition IM, information concerning the shape (density, inclination, and the like) of the pattern of the mold M, information concerning the shape (step and the like) of the substrate S, and information concerning volatilization of the curable composition IM are used. When assigning (reflecting) the feature amounts to the graphs, different graphs are used for different kinds of the feature amounts. For example, in 9b, the positions (coordinates) of the droplets of the curable composition IM are reflected on a graph 902, the density of the pattern of the mold M is reflected on a graph 903, and the step of the substrate S is reflected on a graph 904.

Referring back to FIG. 7, in step S705, feature amounts are assigned to graphs which will serve as learning data of the graph neural network.

Here, with reference to FIGS. 10A and 10B, a process of generating learning data from measurement data will be described. FIG. 10A shows an example of measurement data included in the data group (list) acquired in step S702. The measurement data shown in FIG. 10A includes information concerning the position (location) where a defect 1002 occurs and the size thereof in a shot region 1001 of the substrate S. FIG. 10B shows learning data including information indicating the correspondence between the defect 1002 included in the measurement data shown in FIG. 10A and the droplet of the curable composition IM that has caused the defect 1002. In the learning data shown in FIG. 10B, an arrangement pattern 1004 of the droplets of the curable composition IM and links 1005 each connecting the adjacent droplets of the curable composition IM are generated. In addition, each link 1005 in the learning data shown in FIG. 10B is associated with defects 1006 and 1007 included in the measurement data. The defects 1006 and 1007 occur when the adjacent droplets of the curable composition IM do not merge with each other. Therefore, as the feature amount of the learning data, the merging probability (degree) of the adjacent droplets of the curable composition IM is used. For example, like the link 1005, if the defects 1006 and 1007 have not occurred near the link, the merging probability of the droplets of the curable composition IM existing at both ends of the link 1005 is high. On the other hand, like a link 1008, if the defects 1006 and 1007 have occurred near the link, the merging probability of the droplets of the curable composition IM existing at both ends of the link 1008 is low. In this manner, as an example of the learning data, the merging probability of the droplets of the curable composition IM is assigned as the feature amount to the link. Note that as the feature amount of the learning data, the position and size of the defect, the size of the region surrounded by the links, and the like can also be used.

In the graph neural network, each node of the graph generally has the feature amount. Therefore, for the sake of convenience, a method is also effective in which the feature amount assigned (applied) to the link such as the merging probability of the droplets of the curable composition IM is reassigned as the feature amount to the nodes existing at both ends of the link.

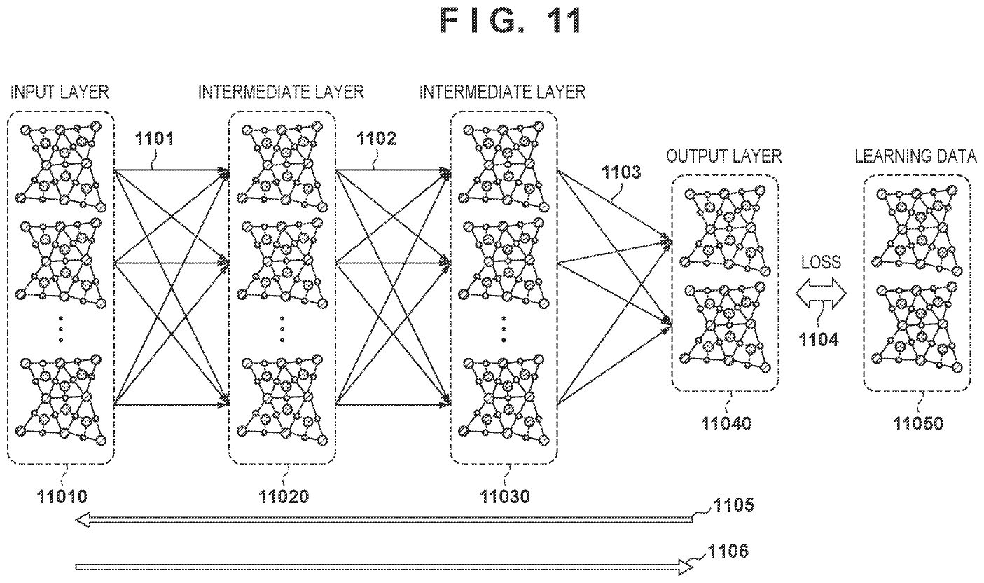

In step S706, a learning model is set. FIG. 11 is a view showing an example of the graph neural network set as the learning model. The graph neural network shown in FIG. 11 is formed from layers including an input layer 11010, two intermediate layers 11020 and 11030, and an output layer 11040. Each layer includes, as elements, graphs for different feature amounts. Weights 1101, 1102, and 1103 between the graphs are associated between the layers. The weights 1101, 1102, and 1103 are expressed as, for example, matrices. The graph neural network has a convolutional effect, and the feature amount of the corresponding node and the feature amounts of the nodes adjacent to the corresponding node in the front layer serve as the inputs (input parameters) of the rear layer. Since the graph neural network shown in FIG. 11 includes the two intermediate layers 11020 and 11030, it is possible to perform learning considering the feature amounts of the nodes which are two ahead of a given node.

In step S707, learning of the learning model set in step S706 is executed. More specifically, the graphs assigned with the feature amounts in step S704, which serve as input parameters, are set for the input layer 11010 of the graph neural network shown in FIG. 11. Further, the graphs assigned with the feature amounts in step S705, which serve as learning data, are set for learning data 11050. During learning, a loss 1104, which expresses the error between the output layer 11040 and the learning data 11050 is calculated, and the weights are updated in a direction 1105 from the output layer 11040 toward the input layer 11010 so as to decrease the loss 1104 as the error.

In step S708, it is determined whether the learning has been executed for all the measurement data included in the data group (list) acquired in step S702. If the learning has not been executed for all the measurement data, that is, if there is the measurement data for which the learning is not complete, the process transitions to step S703, and steps S703 to S707 (learning procedure) are executed. On the other hand, if the learning has been executed for all the measurement data, the process transitions to step S709.

In step S709, the learning model in which the learning is complete is output (that is, the learning model is generated).

As has been described above, by performing the process illustrated in FIG. 7, it is possible to generate the learning model including the graph neural network which has learned the measurement data corresponding to the arrangement pattern of the droplets of the curable composition IM. The learning model generated in this embodiment becomes the learning model including the feature amounts of the adjacent droplets of the curable composition IM and the feature amounts of the droplets farther than the adjacent droplets.

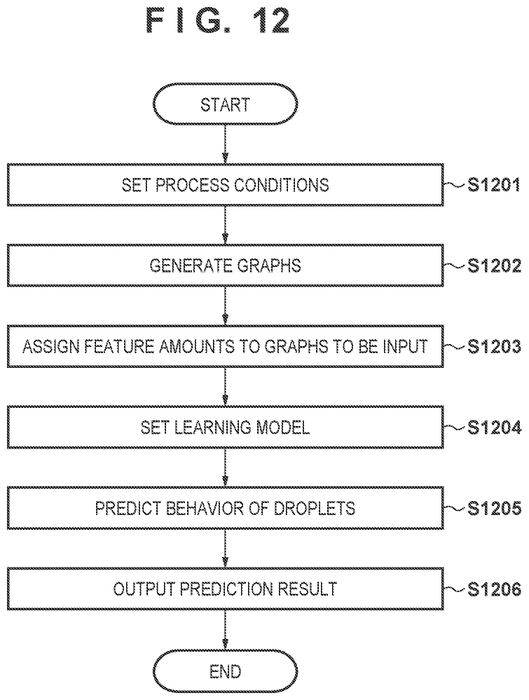

With reference to FIG. 12, a process of predicting the behavior of the droplets of the curable composition IM arranged on the substrate S by using the learning model generated in the process illustrated in FIG. 7 will be described. The behavior of the droplets of the curable composition IM here is the behavior of the droplets of the curable composition IM in a process of forming a film of the curable composition IM in a space between the substrate S and the mold M.

In step S1201, conditions (process conditions) required for a process (for example, imprint process) of forming a film of the curable composition IM in a space between the substrate S and the mold M are set. As has been described above, the process conditions include the arrangement pattern, the shape of the pattern of the mold M, the target value of the thickness of the film of the curable composition IM to be formed on the substrate S, the depth of the pattern (groove) in the pattern region MP of the mold M, and the like.

In step S1202, graphs included in each layer in the graph neural network are generated. The specific process of generating graphs is similar to that in step S703, and the detailed description thereof will be omitted here.

In step S1203, feature amounts are assigned to graphs which will be used as inputs of the graph neural network, that is, the graphs generated in step S1202. The specific process of assigning feature amounts to graphs is similar to that in step S704, and the detailed description thereof will be omitted here.

In step S1204, a learning model is set. Here, the learning model generated in the process illustrated in FIG. 7 is set.

In step S1205, using the learning model set in step S1204, the behavior of the droplets of the curable composition IM in the process of forming a film of the curable composition IM in the space between the substrate S and the mold M is predicted.

Here, with reference to FIG. 11, the procedure of prediction (inference) of the behavior of the droplets of the curable composition IM in step S1205 will be described. As has been described above, in this embodiment, when predicting the behavior of the droplets of the curable composition IM, the learning model generated in the process illustrated in FIG. 7 is used. In this learning model, each of the weights 1101, 1102, and 1103 between the layers, which is expressed by the matrix, has been updated. First, the graphs assigned with the feature amounts in step S1203, which serve as input parameters, are set for the input layer 11010. In the process of prediction, the feature amounts in the graphs are updated in a direction 1106 from the input layer 11010 toward the output layer 11040. Since convolutional processing, which is the effect of the graph convolution network, is performed between the layers, the feature amounts of the adjacent droplets of the curable composition IM in the front layer are reflected on the rear layer.

Referring back to FIG. 12, in step S1206, the behavior of the droplets of the curable composition IM predicted in step S1205 is output as a prediction result. For example, as the prediction result of the behavior of the droplets of the curable composition IM, the degree of merging of the adjacent droplets of the plurality of droplets of the curable composition IM on the substrate is displayed on the display unit 409.

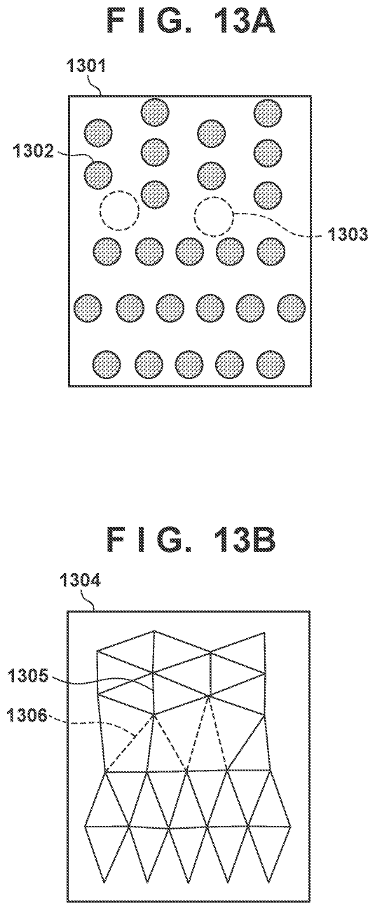

With reference to FIGS. 13A and 13B, an example of the result predicted from an input parameter in this embodiment will be described. FIG. 13A shows the arrangement pattern of the droplets of the curable composition IM serving as the input parameter. Referring to FIG. 13A, the density of droplets 1302 of the curable composition IM is low in a region 1303 in a shot region 1301 of the substrate S. FIG. 13B shows the result (prediction result) predicted in step S1205 with respect to the arrangement pattern of the droplets of the curable composition IM shown in FIG. 13A. In this embodiment, the merging state of the adjacent droplets of the curable composition IM serving as the feature amount is predicted. For example, as shown in FIG. 13B, for a link 1305 indicated by a solid line, it has been predicted that the merging probability of the adjacent droplets of the curable composition IM is high. On the other hand, for a link 1306 indicated by a dashed line, it has been predicted that the merging probability of the adjacent droplets of the curable composition IM is low. Here, the prediction of the merging state of the adjacent droplets of the curable composition IM is used as the feature amount, but the position and size of the defect, the size of the region surrounded by the links, or the like can also be handled as learning data.

As has been described above, according to this embodiment, in a process of predicting the behavior of the droplets of the curable composition IM arranged on the substrate S, the behavior of the droplets of the curable composition IM is predicted using machine learning in place of physical calculation. With this, it is possible to provide a technique of predicting the complex behavior considering the interaction of the plurality of droplets of the curable composition IM even with a small calculation amount.

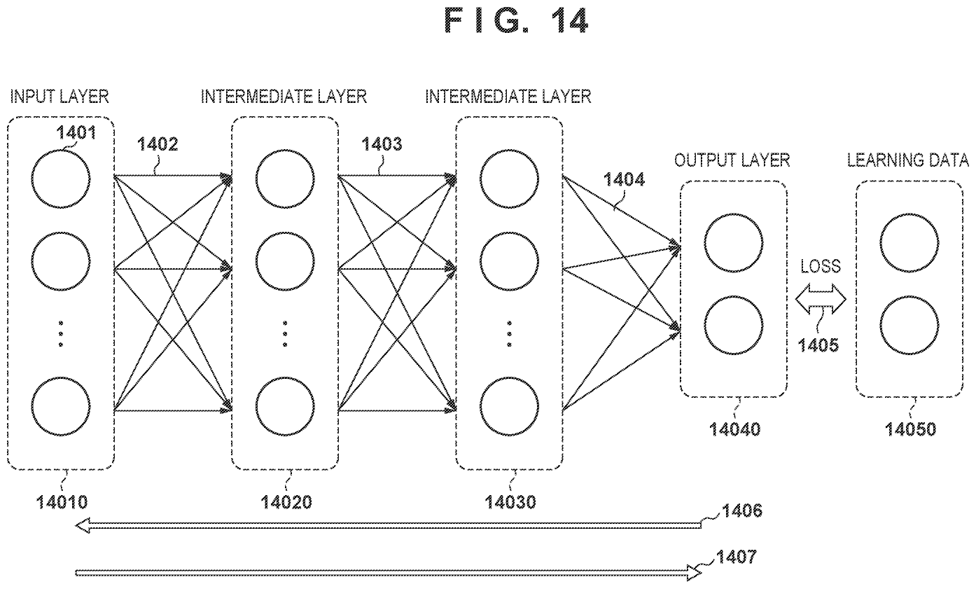

A case has been described in which the graph neural network is used as the learning model in machine learning. However, it is also possible to use a model of a neural network as the learning model as shown in FIG. 14. FIG. 14 is a view showing an example of a neural network.

The neural network is formed from layers including an input layer 14010, one or a plurality of intermediate layers (hidden layers) 14020 and 14030, and an output layer 14040. Each layer includes neurons 1401 as elements, and weights 1402, 1403, and 1404 associate the layers. As in the graph neural network, the weights 1402, 1403, and 1404 between the layers are updated in the neural network. For example, the weights 1402, 1403, and 1404 are updated in a direction 1406 from the output layer 14040 toward the input layer 14010. At this time, the weights 1402, 1403, and 1404 are updated so as to decrease a loss 1405, which expresses the error between learning data 14050 and the output layer 14040 serving as output data.

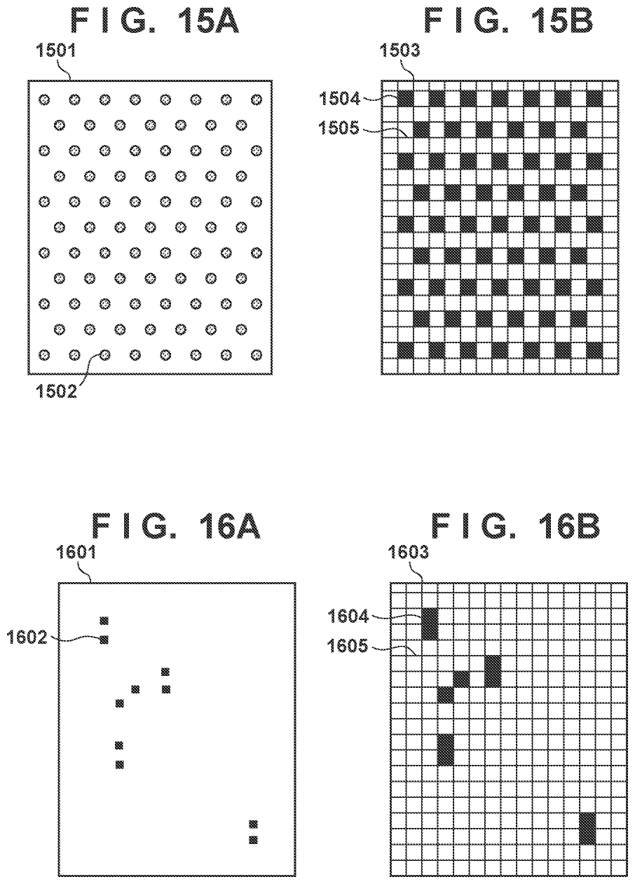

With reference to FIGS. 15A and 15B, input data used for prediction using the neural network will be described. FIG. 15A shows an arrangement pattern 1502 of the droplets of the curable composition IM in a shot region 1501 of the substrate S. FIG. 15B shows data generated as input data of the neural network with respect to the arrangement pattern 1502 shown in FIG. 15A. Here, image data 1503 indicating the relationship among the adjacent droplets of the curable composition IM is generated as the input data. Further, as the information indicating the relationship among the adjacent droplets of the curable composition IM, the density of the droplets of the curable composition IM included in each pixel (region) of the image data 1503 is used. In FIG. 15B, the pixel value (color) of each pixel of the image data 1503 is changed in accordance with the density of the droplets of the curable composition IM. More specifically, a black pixel value is set for a pixel 1504 where the density of the droplets of the curable composition IM is high, and a white pixel value is set for a pixel 1505 where the density of the droplets of the curable composition IM is low.

With reference to FIGS. 16A and 16B, learning data used for learning using the neural network will be described. FIG. 16A shows measurement data for a shot region 1601 of the substrate S, and shows the position and size of each defect 1602 having occurred in the film of the curable composition IM formed on the shot region 1601. FIG. 16B shows data generated as learning data of the neural network for the measurement data shown in FIG. 16A. Here, image data 1603 indicating the positions of the defects having occurred in the film of the curable composition IM is generated as the learning data. In FIG. 16B, the pixel value (color) of each pixel of the image data 1603 is changed in accordance with the presence/absence of the defect. More specifically, a black pixel value is set for a pixel 1604 corresponding to the position where the defect exists, and a while pixel value is set for a pixel 1605 corresponding to the position where no defect exists.

The neural network shown in FIG. 14 is learned using the input data and learning data generated as described above. By using the model of the neural network after learning, as in the graph neural network, it is possible to predict the complex behavior considering the interaction of the plurality of droplets of the curable composition IM arranged on the substrate S.

In this embodiment, a case of predicting the behavior of the droplets of the curable composition IM in a process of forming a film made of a cured product of the curable composition IM by arranging the droplets of the curable composition IM on the substrate S and bringing the mold M into contact with the droplets has been described. However, this embodiment is not limited to the process of forming a film of the curable composition IM by bringing the mold M and the droplets of the curable composition IM into contact with each other. For example, this embodiment is also applicable to a case of forming a film of the curable composition IM by merging adjacent droplets of the curable composition IM arranged on the substrate S. Even in a case as described above in which it is unnecessary to bring the droplets of the curable composition IM on the substrate S and the mold M into contact with each other, it is possible to predict the behavior of the droplets of the curable composition IM while using, as feature amounts, the density of the droplets of the curable composition IM, the shape of the substrate S, the film thickness of the curable composition IM, and the like.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

The film forming apparatus IMP incorporating the prediction server 303 (information processing apparatus) controls a process of forming a film of a curable composition from a plurality of droplets of the curable composition arranged on a first member based on prediction of the behavior of the droplets of the curable composition by the prediction server 303.

An article manufacturing method according to this embodiment includes a step of determining, while repeating a prediction method (simulation) described above, a condition for a process of forming a film of a curable composition from a plurality of droplets of the curable composition arranged on a first member, and a step of executing the process in accordance with the condition. A mode in which a mold includes a pattern has been described so far, but the present invention is also applicable to a mode in which a substrate includes a pattern.

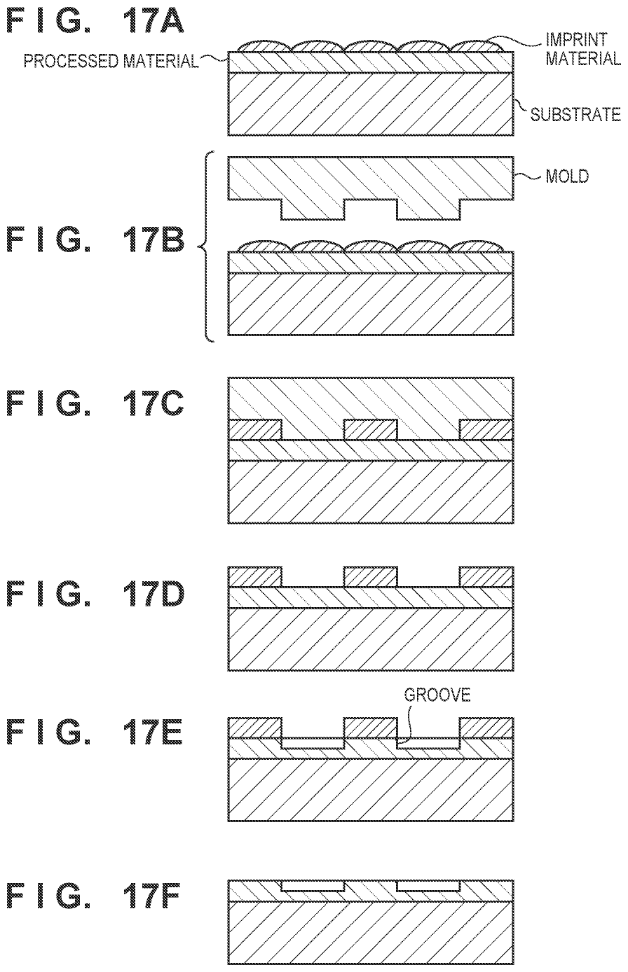

FIG. 17A to FIG. 17F show a more specific example of the method of manufacturing an article. As illustrated in FIG. 17A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 17B, a side of the mold for imprint with a projection and groove pattern is formed on and caused to face the imprint material on the substrate. As illustrated in FIG. 17C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 17D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 17E, when etching is performed using the pattern of the cured product as an etching resistant mask, a portion of the surface of the processed material where the cured product does not exist or remains thin is removed to form a groove. As shown in FIG. 17F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2022-107359 filed Jul. 1, 2022, which is hereby incorporated by reference herein in its entirety.

What is claimed is:

1. A prediction method of predicting a behavior of droplets of a curable composition in a process of forming a film of the curable composition from a plurality of droplets of the curable composition arranged on a first member, the method comprising
predicting the behavior of the droplets using a learning model,
wherein an input of the learning model includes first information indicating positions on the first member to which the droplets of the curable composition are to be arranged.

2. The method according to claim 1, wherein
the input of the learning model includes second information indicating a relative positional relationship among adjacent droplets of the plurality of droplets.

3. The method according to claim 2, wherein
the second information is expressed by a graph formed from nodes and a link connecting the nodes.

4. The method according to claim 3, wherein
in the graph, a position corresponding to each of the plurality of droplets is set as the node, and a line connecting adjacent nodes is set as the link.

5. The method according to claim 4, wherein
the position includes a center position of each of the plurality of droplets.

6. The method according to claim 3, wherein
in the graph, a position in a region defined by adjacent droplets of the plurality of droplets is set as the node, and a line connecting adjacent nodes is set as the link.

7. The method according to claim 6, wherein
the region is a region divided by Voronoi boundaries of a Voronoi diagram in which each of the plurality of droplets is set as a generating point.

8. The method according to claim 6, wherein
the position includes a centroid position of the region.

9. The method according to claim 6, wherein
the position includes a Voronoi boundary of a Voronoi diagram in which each of the plurality of droplets is set as a generating point.

10. The method according to claim 3, wherein
in the graph, a position corresponding to each of the plurality of droplets, a position in a region defined by adjacent droplets of the plurality of droplets, and a position where Voronoi boundaries of a Voronoi diagram intersect, in which each of the plurality of droplets is set as a generating point, are set as nodes, and a line connecting adjacent nodes is set as the link.

11. The method according to claim 3, wherein
in the graph, at least one of the node and the link holds, as a feature amount, one of information concerning a position and a volume of the droplet and information concerning a shape of the first member.

12. The method according to claim 2, further comprising
generating the learning model while using at least one of the first information and the second information as the input and using the predicted behavior of the droplets as learning data.

13. The method according to claim 1, wherein
in the predicting, a degree of merging of adjacent droplets of the plurality of droplets is predicted as the behavior of the droplets.

14. The method according to claim 1, wherein
the process includes a process of bringing the curable composition arranged on the first member and a second member into contact with each other, thereby forming a film of the curable composition in a space between the first member and the second member.

15. The method according to claim 14, wherein
the input of the learning model includes at least one of information indicating a volume of the droplet, information concerning volatilization of the droplet, information concerning a shape of the first member, and information concerning a shape of a pattern provided on the second member.

16. The method according to claim 2, wherein
the learning model uses a graph neural network.

17. The method according to claim 1, wherein
the learning model uses a neural network.

18. An information processing apparatus that predicts a behavior of droplets of a curable composition in a process of forming a film of the curable composition from a plurality of droplets of the curable composition arranged on a first member, wherein
the apparatus predicts the behavior of the droplets using a learning model, and
an input of the learning model includes information indicating positions on the first member to which the droplets of the curable composition are to be arranged.

19. A film forming apparatus incorporating an information processing apparatus defined in claim 18, wherein
a process of forming a film of a curable composition from a plurality of droplets of the curable composition arranged on a first member is controlled based on prediction of a behavior of the droplets of the curable composition by the information processing apparatus.

20. An article manufacturing method comprising:
determining, while repeating a prediction method defined in claim 1, a condition for a process of forming a film of a curable composition from a plurality of droplets of the curable composition arranged on a first member, and
executing the process in accordance with the condition.

21. A non-transitory storage medium storing a program for causing a computer to execute a prediction method defined in claim 1.
